(19) United States
(12) Patent Application Publication
(10) Pub. No.: US 2004/0245602 A1
(43) Pub. Date: Dec. 9, 2004

(54) Method of fabricating metal-insulator-metal capacitor (MIM) using lanthanide-doped HfO2

(76) Inventors: Sun Jung Kim, Singapore (SG); Byung Jin Cho, Singapore (SG); Ming-Fu Li, Singapore (SG); Mingbin Yin, Singapore (SG)

Correspondence Address: PILLSBURY WINTHROP LLP, 2475 HANOVER STREET, PALO ALTO, CA, 94304-1114, US

(21) Appl. No.: 10/843,861

(22) Filed: May 11, 2004

Related U.S. Application Data
(60) Provisional application No. 60/472,622, filed on May 21, 2003.

(51) Int. Cl. H01L 29/00

(52) U.S. Cl. 257/532

(57) ABSTRACT

Briefly, a preferred embodiment of the present invention includes a metal-insulator-metal (MIM) capacitor including a bottom layer of conductive material formed by depositing this conductive material on a substrate. A dielectric material is then formed on the bottom conductive layer, wherein the dielectric material is preferably an HfO₂ dielectric doped with lanthamide material, more preferably Th doped HfO₂ with a Th concentration in the range of 0 to 6% and more particularly substantially 4%. A top conductive layer is formed on top of the dielectric.

The present application claims priority from U.S. provisional patent application Ser. No. 60/472,622 filed May 21, 2003.

### BACKGROUND OF THE INVENTION

1. Field of Invention

The present invention relates generally to capacitors, and more particularly to a metal-insulator-metal capacitor with a lanthamide doped HfO₂ dielectric.

2. Description of the Prior Art

The metal-insulator-metal (MIM) capacitor is a key passive component in RF/mixed signal ICs. Most semiconductor foundries provide MIM capacitor modules with a capacitance density ranging from 1 to 2 fF/μm² using SiO₂ or Si₃N₄ based dielectrics. Meanwhile, it is predicted that the industry will require capacitors with a capacitance density higher than 12 fF/μm² for RF bypass capacitor applications by year 2006. This requirement would be achievable if an insulator with a dielectric constant higher than 57 were available, considering the present dielectric thickness of around 50 nm. Materials such as BST, TaOₓ, and TiOₓ exhibit high dielectric constant values of 60 or above if crystallized by high temperature annealing, but such high temperature annealing is not realistic in a back-end of line process. Instead, amorphous dielectrics such as Al₂O₃, Ta₂O₅, and HfO₂ have recently been investigated for MIM capacitor application, but due to their dielectric constants K ranging only from 9 to 25, the dielectric thicknesses of capacitors using these materials would have to be reduced to thinner than 20 nm in order to meet the projected year 2006 capacitor density requirements for bypass capacitor applications. The use of such thin dielectrics would cause problems, such as high leakage current and a poor voltage coefficient of capacitance (VCC).

### SUMMARY

It is therefore an object of the present invention to provide an improved MIM capacitor.

It is a further object of the present invention to provide an MIM capacitor that has an improved capacitance density.

It is a still further object of the present invention to provide an MIM capacitor with an improved voltage coefficient of capacitance and improved capacitance density.

Briefly, a preferred embodiment of the present invention includes a metal-insulator-metal (MIM) capacitor including a bottom layer of conductive material formed by depositing this conductive material on a substrate. A dielectric material is then formed on the bottom conductive layer, wherein the dielectric material is preferably an HfO₂ dielectric doped with lanthamide material, more preferably Tb doped HfO₂ with a Tb concentration in the range of 0 to 6% and more particularly substantially 4%. A top conductive layer is formed on top of the dielectric.

### IN THE DRAWING

FIG. 1 illustrates construction of the metal-insulator-metal capacitor of the present invention;

FIG. 2 is a graph showing the linear and quadratic capacitance voltage coefficient v.s. Th concentration for a capacitor according to the present invention;

FIG. 3 is a graph showing capacitance density v.s. frequency for a variety of Tb concentrations;

FIG. 4 is a graph showing current density v.s. bias voltage for a variety of Th concentrations; and

FIG. 5 is a graph of leakage current and capacitance density v.s. Tb concentrations.

### DETAILED DESCRIPTION OF THE PREFERRED EMBODIMENTS

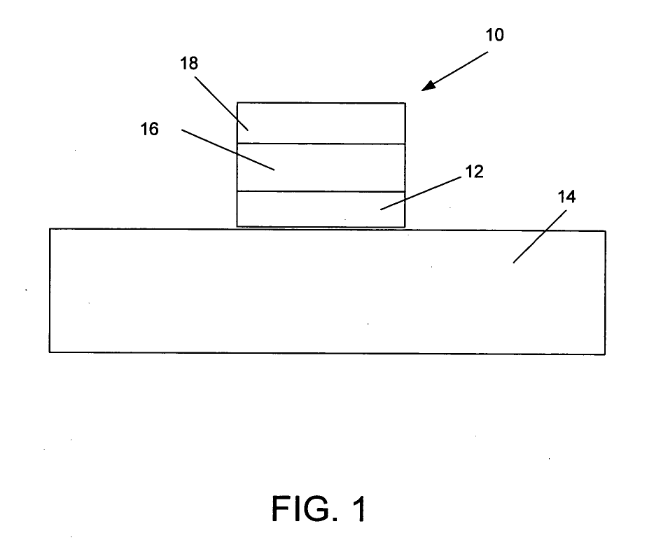

A preferred embodiment of the present invention will now be described in reference to FIG. 1 of the drawing. A metal-insulator-metal capacitor 10 is shown having a bottom layer 12 of conductive material, formed in this example as deposited on a substrate 14. A dielectric material 16 is formed on the conductive bottom layer 12, and a conductive top layer 18 is formed on top of the dielectric layer 16. According to the present invention, the dielectric layer 16 is a lanthamide doped metal oxide. Particular and preferred lanthamides are metal oxides and their proportions and performance will be described in detail in the following disclosure.

The structure shown in FIG. 1 is given by example for use in explanation of the nature of the present invention, which includes a lanthamide doped metal oxide insulation dielectric layer/spacing between conductive layers. Other capacitance structures having a lanthamide doped metal oxide insulation dielectric layer are also included in the spirit of the present invention. For example, the top conductor 18 could be polysilicon, and the bottom conductor could be a doped substrate. An example of an alternate construction would be a lanthamide dielectric slab first constructed, and then conductive top and bottom layers applied. Various ways of constructing conductive plates/layers for a capacitor will be apparent to those skilled in the art, and these are to be included in the spirit of the present invention in combination with the novel dielectric 16 disclosed herein.

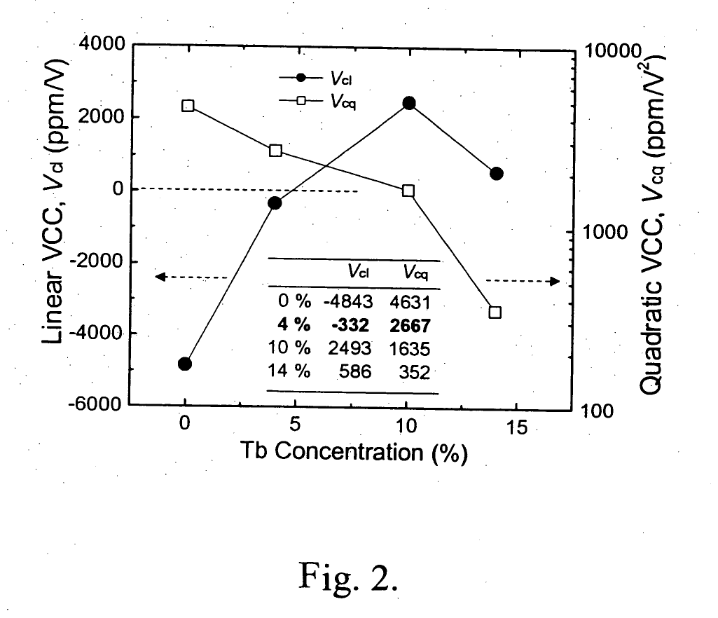

The deposition of the lanthamide doped metal oxide 16 can be accomplished by methods that will be apparent to those skilled in the art, and these are included in the spirit of the present invention. One method is to co-sputter the lanthamide and HfO₂ onto the conductive layer 12. Co-sputtering is a method that can deposit more than one material by applying DC/RF power to all the required sputter targets. The composition ratio can be adjusted by controlling the respective sputter target powers. Alternatively, one can use a single composite target which contains both Hf and lanthamide material. Other methods include chemical vapor depositions (CVD) using a lanthamide doped dielectric precursor, and atomic layer deposition (ALD) for depositing laminates of lanthamide-oxide and other metal oxides including the preferred metal oxide HfO₂ The present invention also includes other lanthamide doped metal oxides such as Al₂O₃, Ta₂O₅ and TiO₂. The atomic percentage of lanthamides in the dielectrics deposited by the above mentioned methods are in the range of 4 to 20%. The specific lanthamide used can be selected from the lanthamide series of materials such as Tb, Dy and Nd. A preferred embodiment of the present invention is a capacitor with a dielectric of HFO₂ doped with Tb. The performance of this dielectric will be reported in reference to FIGS. 2-5. In this embodiment a preferred Th doping range is from about 3 to 5%, and a more preferred doping is substantially 4%.

The lanthamide doped metal oxide dielectric of the present invention provides a high capacitance density, and simultaneously a low voltage coefficient of capacitance and low leakage current. As will be illustrated in FIGS. 2-5, the percentage of doping in order to achieve this result must be in a certain range, and as such is critical. This result is unexpected/unanticipated by the prior art and is highly advantageous, being a solution to a problem of significant concern.

FIGS. 2-5 illustrate a result using Tb doped HfO₂. This dielectric allows a 13.3 fF/m² capacitance density with leakage current and VCC values that fully meet ITRS (international technology roadmap for semiconductors) requirements for year 2006 for RF bypass capacitor applications.

FIG. 2 is a graph showing the linear voltage coefficient (Vcl) and quadratic voltage coefficient (Vcq) as a function of Tb doping concentration. Vcq decreases with increasing Th concentration. The smallest Vcl of −332 ppm/V was achieved at a 4% Tb concentration. Near zero Vcl is obtainable with Tb doping. Note the unexpected result of a very small Vcl and Vcq at a doping level around 4-6%.

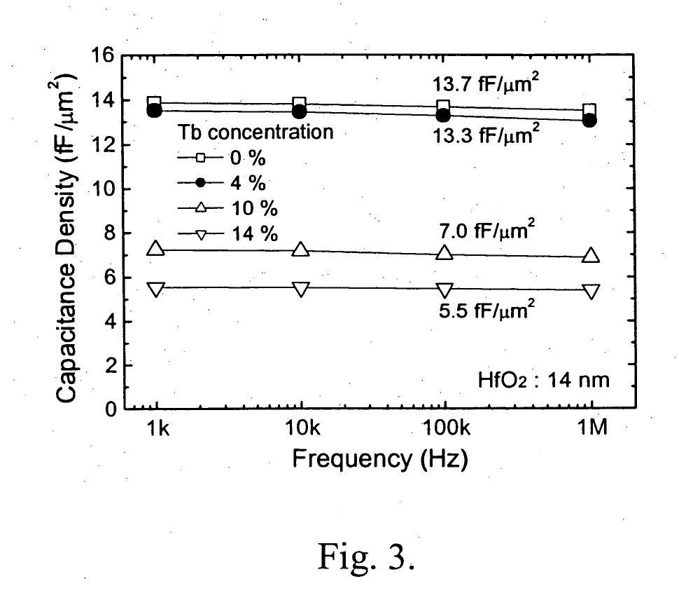

FIG. 3 shows capacitance density as a function of frequency of an applied signal to the capacitor. The relatively flat response curves indicate good frequency characteristics. High densities of 13.7 and 13.2 fF/μm² are achieved with a 4% Tb doping of pure HfO₂.

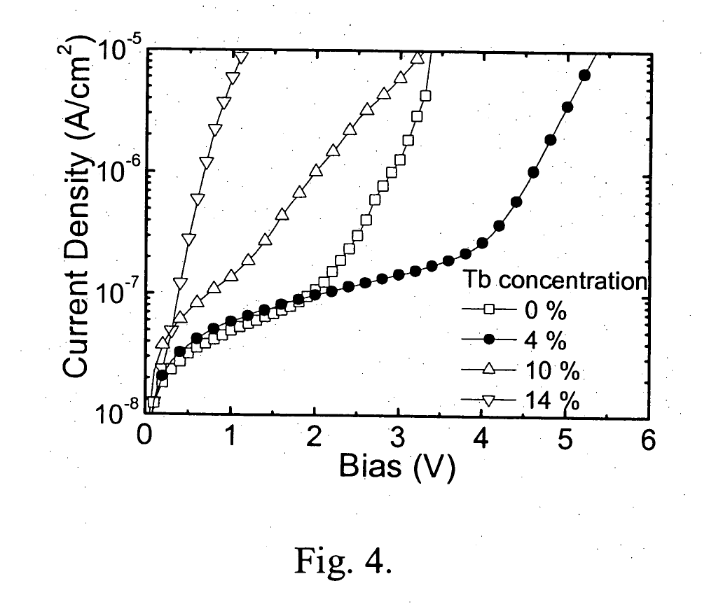

FIG. 4 is a graph of current density versus bias voltage. Remarkably, the current density is also minimized at or near the 4% Th doping level.

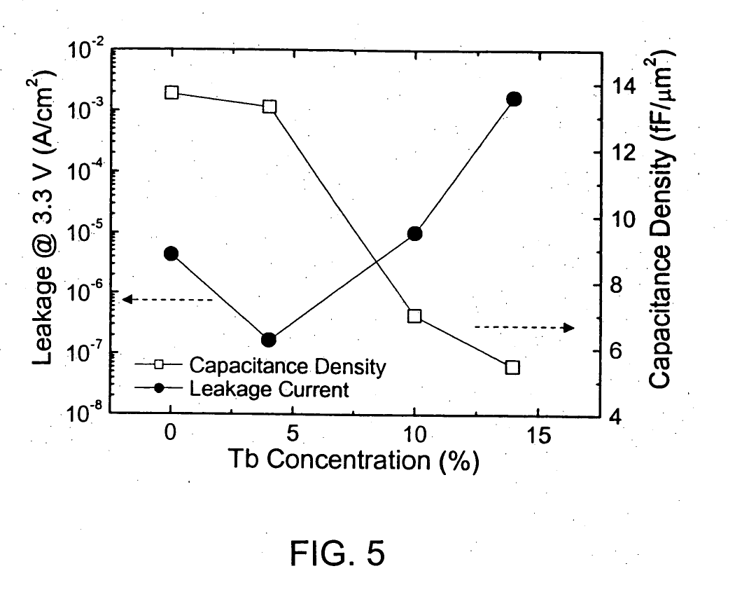

FIG. 5 is a graph of leakage current (with an applied voltage of 3.3 volts) and capacitance density as a function of Tb concentration. Again, a desirable high level of capacitance density and desirable low leakage both occur at a substantially 4% Th doping level. The frequency of applied signal was 100 kHz.

Although the present invention has been described above in terms of a specific embodiment, it is anticipated that alterations and modifications thereof will no doubt become apparent to those skilled in the art. It is therefore intended that the following claims be interpreted as covering all such alterations and modifications as fall within the true spirit and scope of the invention.

What is claimed is:

1. A capacitor comprising:
(a) a first electrically conductive layer;
(b) a second electrically conductive layer; and
(c) a dielectric for insulating said first conductive layer from said second conductive layer, wherein said dielectric consists of a metal oxide doped with a lanthamide.

2. A capacitor as recited in claim 1 wherein said metal oxide is selected from the group consisting of Al₂O₃, HfO₂, Ta₂O₅ and TiO₂.

3. A capacitor as recited in claim 1 wherein an atomic percentage of the lanthamide is from 4 to 20%.

4. A capacitor as recited in claim 1 wherein the metal oxide is HfO₂.

5. A capacitor as recited in claim 4 wherein the lanthamide is Tb.

6. A capacitor as recited in claim 5 wherein an atomic percentage of Th is from 2 to 7%.

7. A capacitor as recited in claim 5 wherein an atomic percentage of Tb is from 3-5%.

8. A capacitor as recited in claim 5 wherein an atomic percentage of Th is substantially 4%.

9. A method of constructing a capacitor comprising:
forming a dielectric with a first electrically conductive layer and a second conductive layer thereon, and said first and second dielectrics spaced apart by said dielectric, wherein said dielectric consists of a metal oxide doped with a lanthamide.

10. A method as recited in claim 9 wherein said metal oxide is selected from the group consisting of Al₂O₃, HfO₂, Ta₂O₅ and TiO₂.

11. A method as recited in claim 9 wherein an atomic percentage of the lanthamide is from 4 to 20%.

12. A method as recited in claim 9 wherein the metal oxide is HFO₂.

13. A method as recited in claim 12 wherein the lanthamide is Th.

14. A method as recited in claim 13 wherein an atomic percentage of Tb is from 2 to 7%.

15. A method as recited in claim 13 wherein an atomic percentage of Tb is from 3-5%.

16. A method as recited in claim 13 wherein an atomic percentage of Tb is substantially 4%.
